(19) United States
(12) Patent Application Publication
(10) Pub. No.: US 2008/0138988 A1
(43) Pub. Date: Jun. 12, 2008

(54) DETECTION OF CLEARANCE OF POLYSILICON RESIDUE

(76) Inventors: Jeffrey Drue David, San Jose, CA (US); Jun Qian, Sunnyvale, CA (US); Garrett Sin, San Jose, CA (US); Daxin Mao, San Jose, CA (US); Chris Heung-Gyun Lee, San Jose, CA (US); Sivakumar Dhandapani, San Jose, CA (US); Boguslaw A. Swedek, Cupertino, CA (US); Dominic J. Benvegnu, La Honda, CA (US); Lakshmanan Karuppiah, San Jose, CA (US)

Correspondence Address: FISH & RICHARDSON P.C., P.O. BOX 1022, MINNEAPOLIS, MN, 55440-1022, US

(21) Appl. No.: 11/952,777

(22) Filed: Dec. 7, 2007

Related U.S. Application Data
(60) Provisional application No. 60/869,106, filed on Dec. 7, 2006.

(51) Int. Cl. H01L 21/302

(52) U.S. Cl. 438/692

(57) ABSTRACT

During polishing of a substrate, polysilicon can be removed from a surface of the substrate. Detecting an endpoint during polishing of polysilicon can include polishing the substrate having a polysilicon residue on an area of oxide area and optically detecting clearance of the polysilicon residue.

### CROSS-REFERENCE TO RELATED APPLICATIONS

This application claims priority to U.S. Provisional Application Ser. No. 60/869,106, filed on Dec. 7, 2006. The disclosure of the prior application is considered part of and is incorporated by reference in the disclosure of this application.

### BACKGROUND

This invention relates to polishing endpoint detection.

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the conductive layer remaining between the raised pattern of the insulative layer form vias, plugs, and lines that provide conductive paths between thin film circuits on the substrate. For other applications, such as oxide polishing, the filler layer is planarized until a predetermined thickness is left over the non planar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing disk pad or belt pad. The polishing pad can be either a standard pad or a fixed abrasive pad. A standard pad has a durable roughened surface, whereas a fixed-abrasive pad has abrasive particles held in a containment media. The carrier head provides a controllable load on the substrate to push it against the polishing pad. A polishing slurry is typically supplied to the surface of the polishing pad. The polishing slurry includes at least one chemically reactive agent and, if used with a standard polishing pad, abrasive particles.

One problem in CMP is determining whether the polishing process is complete, i.e., whether a substrate layer has been planarized to a desired flatness or thickness, or when a desired amount of material has been removed. Overpolishing (removing too much) of a conductive layer or film leads to increased circuit resistance. On the other hand, underpolishing (removing too little) of a conductive layer leads to electrical shorting. Variations in the initial thickness of the substrate layer, the slurry composition, the polishing pad condition, the relative speed between the polishing pad and the substrate, and the load on the substrate can cause variations in the material removal rate. These variations cause variations in the time needed to reach the polishing endpoint. Therefore, the polishing endpoint cannot be determined merely as a function of polishing time.

### SUMMARY

A method of detecting a endpoint during polishing of polysilicon, comprising polishing a substrate having polysilicon residue on an oxide area, and optically detecting clearance of the polysilicon residue is described.

Implementations of the invention can include one or more of the following features. Optically detecting clearance can include selecting a reference spectrum, obtaining a current spectrum in-situ during polishing, and determining a polishing endpoint based on the reference spectrum and the current spectrum. Determining the polishing endpoint can include calculating a difference between the reference spectrum and the current spectrum. The reference spectrum can correspond to a spectrum from immediately after clearance of the polysilicon residue. Selecting the reference spectrum can include polishing a test substrate and obtaining a test spectrum in-situ during polishing of the test substrate. Selecting the reference spectrum can further include observing the test spectrum, observing a sudden change in the 550-800 nm wavelength range of the test spectrum that occurs after initial exposure of the oxide, and selecting the reference spectrum proximally after the sudden change. Selecting the reference spectrum can further include calculating a difference between the test spectrum and a test reference spectrum corresponding to initial exposure of the oxide, detecting an inflection in the differential signal that occurs after initial exposure of the oxide, and selecting the reference spectrum proximally after the inflection.

### DESCRIPTION OF DRAWINGS

FIGS. 1A-1E illustrate polishing of a polysilicon layer on a substrate.

FIG. 2 illustrates a differential signal obtained during polishing of a polysilicon layer.

FIGS. 3A and 3B illustrate spectra from before and after clearing of the polysilicon from the oxide posts.

FIG. 4 illustrates a differential signal obtained during polishing of a polysilicon layer using the spectra from FIG. 3B.

Like reference symbols in the various drawings indicate like elements.

### DETAILED DESCRIPTION

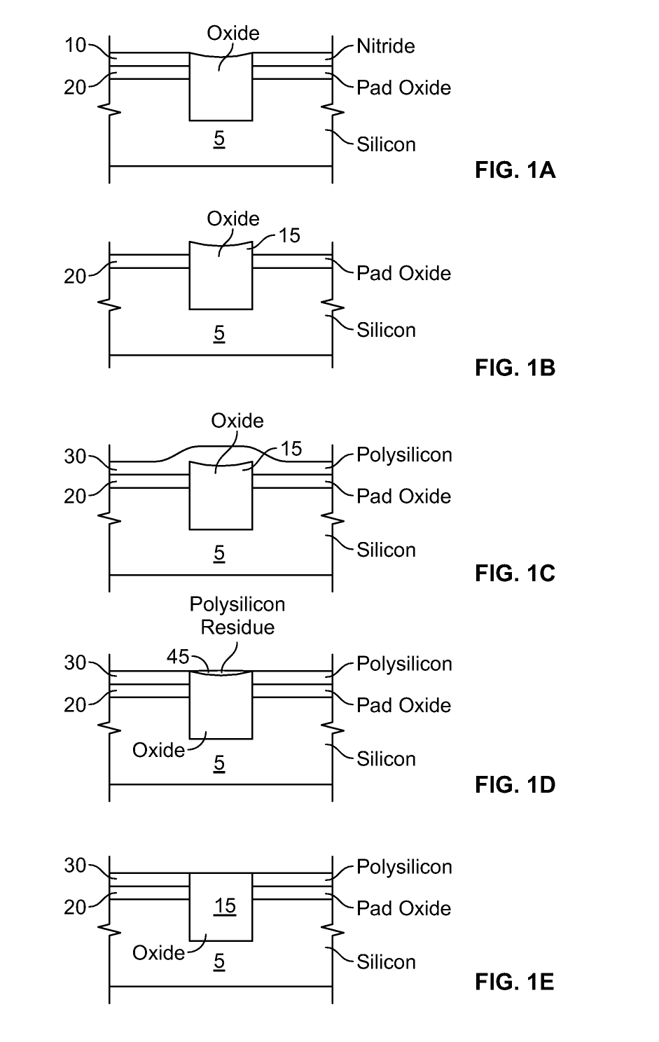

As shown in FIGS. 1A-1E, one process used in integrated circuit manufacturing is, after shallow trench isolation, to strip an outer nitride layer 10 (FIGS. 1A and 1B) leaving oxide posts 15 projecting above the oxide pads 20. The oxide posts 15 have a thickness greater than the oxide pads 20, and can extend down into a substrate 5 on which the posts 15 and pads 20 are located. Polysilicon 30 is deposited over the substrate 5 (FIG. 1C), and then chemically mechanically polished to expose the oxide posts 15 (FIG. 1D). The removal of the polysilicon is termed the “bulk” polysilicon removal process.

However, after the “bulk” polysilicon removal process, some polysilicon may remain on the top surface of the oxide posts. Without being limited to any particularly theory, this polysilicon may be left in recesses on the top surface of the oxide posts created by dishing that occurs during polishing in the shallow trench isolation step. It is advantageous for this polysilicon residue to be completely removed from the oxide posts that isolate the polysilicon (FIG. 1E). Conventionally, this removal is done by overpolishing, e.g., continuing to polish the substrate for a preselected time after detection of exposure of the oxide posts. However, since the time required for clearing the polysilicon from the posts can vary from wafer to wafer, the preselected time needs to accommodate substrates that take the longest to clear.

As described below, it is possible to optically detect that the polysilicon has cleared (or is clearing) from the oxide posts. This permits polishing timing or endpoints to be terminated accurately, thereby saving time relative to the conventional time-based overpolishing process.

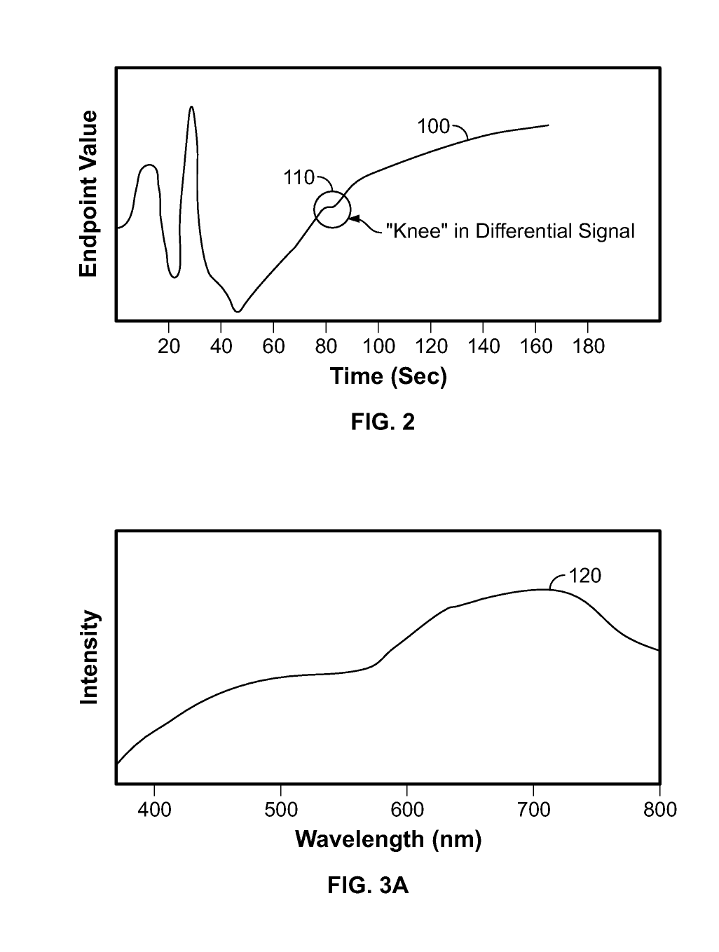

A substrate undergoing polysilicon polishing can be polished using a spectrum-based optical monitoring system to generate a differential signal, an example of which is shown in FIG. 2, as described in U.S. Publication No. 20070042675, published Feb. 22, 2007, the entire disclosure of which is incorporated by reference. The differential signal of FIG. 2 is generated using a target or reference spectrum 100 corresponding to the initial exposure of the oxide posts.

It has been found that after the bulk polysilicon polishing step, the light spectra reflected by the substrate changes little during the residue clearing portion of the polishing operation. In addition, without being limited to any particular theory, as the polysilicon is being cleared from the oxide posts, it is also being removed over the oxide pads, and the change in the spectra due to the removal of the polysilicon over the pad is larger than the change in signal due to the clearance of the polysilicon over the posts.

It has been found however that there is a shift in the rate of change of the normalized spectra at a point where the polysilicon residue begins to clear. This change is stronger in the 550-800 nm range. This can be detected using a test substrate, and a target or reference spectrum can be selected from immediately after the change and be used to generate the differential signal in the spectrum-based optical monitoring process for subsequent substrates. The target or reference spectrum can be stored in memory for accessing. In some embodiments, a test substrate is run for each lot of product substrates to be polished to determine the target or reference spectrum.

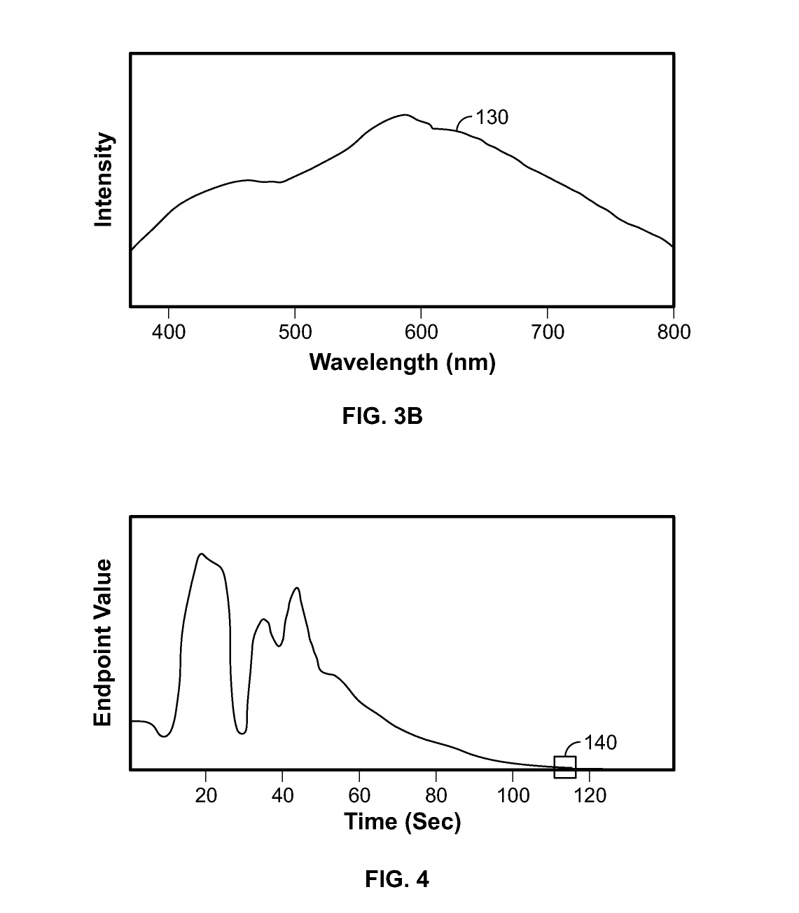

In particular, as shown in FIG. 2, in a differential trace based on a target or reference spectrum corresponding to the initial exposure of the oxide posts, the trace undergoes a small “knee” 110 (the region with a small inflection) that corresponds to the polysilicon clearing step. FIG. 3A illustrates a spectra from before the “knee” 110, whereas FIG. 3B illustrates a spectra from after the “knee” 110. In the examples shown, in FIG. 3A the spectra 120 has an intensity prior to the “knee” 110 that is greatest at about 700 nm and slowly slopes downwardly as a function of wavelength on either side peak intensity. In FIG. 3B, the spectrum 130 after the “knee” 110 has a peak intensity around 590 nm. The intensity then shows a much steeper decline as the wavelength increases or decreases from the peak intensity. Thus, the spectra from immediately after the knee 110, e.g., the spectrum of FIG. 3B, can be selected as a target or reference for polishing of subsequent substrates.

Assuming such a spectra is used, the resulting differential signal will have a minimum 140 at the polysilicon clearing from over the oxide post, as shown in FIG. 4, and this minimum 140 can be detected and used as the polishing endpoint. Polishing can be stopped once the endpoint is reached.

Embodiments of the invention and all of the functional operations described in this specification can be implemented in digital electronic circuitry, or in computer software, firmware, or hardware, including the structural means disclosed in this specification and structural equivalents thereof, or in combinations of them. Embodiments of the invention can be implemented as one or more computer program products, i.e., one or more computer programs tangibly embodied in an information carrier, e.g., in a machine readable storage device or in a propagated signal, for execution by, or to control the operation of, data processing apparatus, e.g., a programmable processor, a computer, or multiple processors or computers. A computer program (also known as a program, software, software application, or code) can be written in any form of programming language, including compiled or interpreted languages, and it can be deployed in any form, including as a stand alone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

It will be understood that various modifications may be made without departing from the spirit and scope of the invention. Accordingly, other embodiments are within the scope of the following claims.

What is claimed is:

1. A method of detecting an endpoint during polishing of polysilicon, comprising:
polishing a substrate having polysilicon residue on an area of oxide; and
optically detecting clearance of the polysilicon residue.

2. The method of claim 1, wherein optically detecting clearance comprises selecting a reference spectrum, obtaining a current spectrum in-situ during polishing, and determining a polishing endpoint based on the reference spectrum and the current spectrum.

3. The method of claim 2, wherein determining the polishing endpoint comprises calculating a difference between the reference spectrum and the current spectrum.

4. The method of claim 3, wherein the reference spectrum corresponds to a spectrum from immediately after clearance of the polysilicon residue.

5. The method of claim 4, wherein selecting the reference spectrum comprises polishing a test substrate and obtaining a test spectrum in-situ during polishing of the test substrate.

6. The method of claim 5, wherein selecting the reference spectrum further comprises observing the test spectrum, observing a sudden change in the 550-800 nm wavelength range of the test spectrum that occurs after initial exposure of the oxide, and selecting the reference spectrum proximally after the sudden change.

7. The method of claim 5, wherein selecting the reference spectrum further comprises calculating a difference between the test spectrum and a test reference spectrum corresponding to initial exposure of the oxide, detecting an inflection in the differential signal that occurs after initial exposure of the oxide, and selecting the reference spectrum proximally after the inflection.

8. A method of detecting an endpoint, comprising:
receiving a spectrum during polishing of a substrate having polysilicon residue on an oxide area; and
optically detecting clearance of the polysilicon residue using the spectrum.

9. A computer program product, tangibly stored on machine readable medium, the product comprising instructions operable to cause a processor to:
receive a spectrum during polishing of a substrate having polysilicon residue on an oxide area; and
detect clearance of the polysilicon residue from a spectrum.

10. The product of claim 9, wherein the instructions to cause a processor to optically detect include instructions to cause a processor to select a reference spectrum, receive a current spectrum in-situ during polishing, and determine a polishing endpoint based on the reference spectrum and the current spectrum.

11. The product of claim 10, wherein the instructions to cause a processor to determine a polishing endpoint include instructions to cause a processor to calculate a difference between the reference spectrum and the current spectrum.

12. The product of claim 11, wherein the reference spectrum corresponds to a spectrum from immediately after clearance of the polysilicon residue.

13. The product of claim 12, wherein the instructions to cause a processor to select the reference spectrum include instructions to cause a processor to receive a test spectrum in-situ during polishing of the test substrate.

14. The product of claim 13, wherein the instructions to cause a processor to select the reference spectrum further comprise instructions to select the reference spectrum proximally after a sudden change in the test spectrum, wherein the sudden change is in the 550-800 nm wavelength range of the test spectrum and occurs after initial exposure of the oxide.

15. The product of claim 13, wherein the instructions to cause a processor to select the reference spectrum further comprise instructions to cause a processor to calculate a difference between the test spectrum and a test reference spectrum corresponding to initial exposure of the oxide, determine when an inflection in the differential signal occurs after initial exposure of the oxide, and select the reference spectrum proximally after the inflection.
